(19) United States
(12) Patent Application Publication
(10) Pub. No.: US 2026/0229145 A1
(43) Pub. Date: Aug. 6, 2026

(54) SELF-LOCKING ELECTRONIC CIRCUIT TESTER WITH BUILT-IN PORTABLE POWER DISTRIBUTOR

(71) Applicant: CODEBENDER R&D HELLAS MONOPROSOPI IKE, PATRAS (GR)

(72) Inventor: VASILEIOS GEORGITZIKIS, PATRAS (GR)

(73) Assignee: CODEBENDER R&D HELLAS MONOPROSOPI IKE, PATRAS (GR)

(21) Appl. No.: 19/149,304

(22) PCT Filed: Jan. 24, 2024
(86) PCT No.: PCT/EP2024/051645

§ 371 Date: Jul. 18, 2025

(30) Foreign Application Priority Data
Jan. 25, 2023 (GR) 20230100056

(51) Int. Cl. G09B 23/18; G01R 1/04; H01R 13/639

(52) U.S. Cl. CPC G09B 23/183; H01R 13/639; G01R 1/0416

(57) ABSTRACT

The present invention relates to a device for the experimental arrangement of electronic circuits with a built-in power distributor, which is self-locking to other of electronic circuits experimental devices. The power distributor of the device receives a stabilized first voltage through a socket of any type from any external device providing compatible output, creates a second voltage from the first voltage and supplies the first and/or the second voltage to the electronic circuit experimental device. The latter can be secured through 3D connectors which are compatible with 3D connection elements of other experimental electronics devices circuits. In alternative implementations the power distributor can include also some of a voltage regulator, a voltage selector, a dimmer, a voltmeter, an ammeter and a battery.

### REFERENCE TO RELATED APPLICATIONS

This application claims priority to and the benefit of GR20230100056, filed on Jan. 25, 2023.

### BACKGROUND

### State of the Art

Experimental Electronic Circuit Layout Devices or otherwise devices for rapid development and testing of electronic circuits, known as Breadboards, are widely used for easy, fast, inexpensive and reversible implementation and testing of electronic circuits. Breadboards have been available for several decades in different forms, dimensions and complexity.

In its general form, a breadboard consists of one or more two-dimensional arrays, where each cell of the array is a socket dimensioned to fit and largely secure a metal terminal of an electronic component (e.g. resistor, capacitor, diode, integrated circuit, etc.) in the socket. The terminal is in the form of a wire or metal leg with a standardized cross-section or maximum transverse dimension which is approximately equal to the cross-section or maximum transverse dimension of each cell-socket of the breadboard.

Breadboards also contain voltage supply lines which lines are selectively connected to rows or columns of the array in order to supply voltage to the electronic components connected to the array. Correspondingly, in the case of connecting integrated circuits (microchips) to the board, in addition to the voltage supply, the cells of the board can be used to implement a data bus or a control bus. A voltage source, or a power supply (henceforth “power supply”) is usually used to power a breadboard, which is usually a device independent of the breadboard to which it is connected via two or more removable cables, while in other cases, an integrated device is used which includes one or more breadboards and a power supply which are connected via fixed-non-removable cables. Both the power supply and the complete device have a large volume and weight compared to the breadboard as they include a number of circuits, such as a transformer and voltage rectifier, a system to protect electronic circuits from overvoltage, etc.

The volume and weight of these devices make their use and transport difficult. Especially the easy transfer of the breadboard is important as in many cases it is necessary to connect electronic elements to the breadboard in order to verify their functional status or damage. This process very often needs to be done in the field rather than in the laboratory, which requires light and unbulky breadboards and power supplies or integrated devices. Such lightweight integrated devices with breadboard are not known in the literature.

At the same time there are examples of breadboards which are powered by batteries to achieve easier use in the field, but even in this case there are problems and disadvantages. For example, as the batteries are easily depleted, they require frequent replacement or recharging, thus creating the additional logistics problem that the SPDIK user must bring with him to the field at least one spare battery and/or charge the SPDIK battery before each use. Furthermore, since the batteries used are usually bulky and heavy, they present similar disadvantages and limitations as the above-mentioned integrated devices.

In addition to the above problems, in the case of using breadboards with an external-independent power supply or battery, both the independent power supply and the battery are connected to the breadboard via removable cables, which cables make it difficult to use the breadboard in the field, as the user must additionally handle the removable cables as well as the mains power supply cable.

Finally, breadboards can be connected to a self-locking power distributor that locks through one or more pairs of three-dimensional protrusions-recesses so that they behave as a single device. Although this configuration allows for easier use in the field outside the laboratory, the electrical connection of the breadboard to the power unit remains problematic as it is vulnerable to damage that may occur if the means providing the electrical connection are disconnected for any reason, e.g. if the media is cut off, accidentally disconnected, or short-circuited. An additional problem of this configuration is the increased size of the combination device which consists of the breadboard and the power unit and which can make it difficult to use, or make it more vulnerable to accidents, e.g. unlocking the power unit from the breadboard with or without breaking the three-dimensional protrusions that keep them secured.

### SUMMARY

### Problem Definition

It is, therefore, apparent to any person skilled in the art that a breadboard device is needed which facilitates use in the field and elsewhere and which device can be designed to be easy to use and easy to manufacture and resistant to strains.

### Proposed Solution

Self-Securing Breadboard with Built-in Portable Power Distributor (BBPPD).

The present invention relates to a BBPPD and can be implemented in different ways as presented below in implementation examples. The common feature of all exemplary embodiments is the use of a Universal Serial Bus (USB) connector of any version (e.g. B, C, micro, etc.) to easily provide power from any device equipped with a USB connector of any version and type, as well as, morphological characteristics for securing the BBPPD to a breadboard. In alternative exemplary implementations, the socket can be of any type, such as e.g. barrel jack, molex, or other.

The present invention also relates to a method of providing power to BBPPDs and external breadboards.

### DESCRIPTION

### Breadboard According to the State of the Art

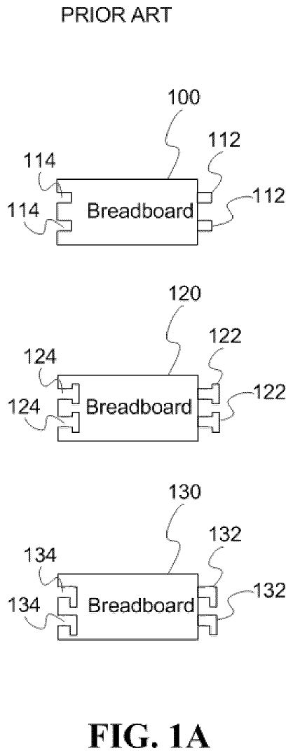

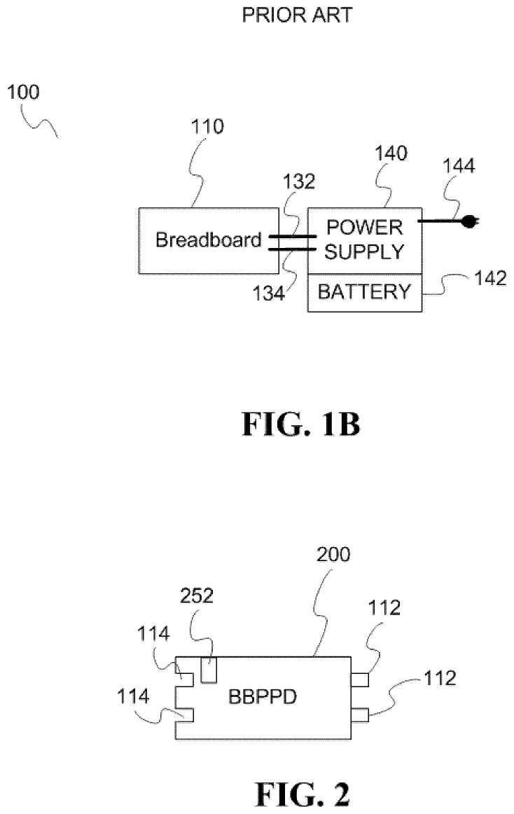

FIG. 1A shows examples of a State-of-the-Art breadboard. A first breadboard (100) has a rectangular (or square) shape and includes on an external surface one or more arrays (not shown) whose cells are sockets for terminals of electronic components. The first breadboard (100) includes on one of its external surfaces, essentially perpendicular to the surface carrying the one or more arrays, one or more three-dimensional connection elements. Each three-dimensional connection element is of a protrusion type (112) (e.g., square, parallelogram, triangular, prismatic, cylindrical, elliptical, or other cross-section). On another outer surface thereof, parallel to the outer surface bearing the three-dimensional projection-type connection element (112), breadboard (100) includes one or more three-dimensional recess-type connection elements (114), each of which is shaped and dimensioned to allow insertion and locking of one of the three-dimensional protrusion-type connecting elements (112). The use of three-dimensional protrusion-type connecting element (112) and recess (114) type connectors allow two or more breadboards (100) to be securely locked together to create a larger board with receptacles for electronic component terminals.

FIG. 1A also shows a second breadboard (120) which is rectangular (or square) in shape and includes one or more arrays (not shown) whose cells are receptacles for electronic component terminals. The second breadboard (120) includes on one of its external surfaces, substantially perpendicular to the surface carrying the one or more panels, one or more three-dimensional connection elements. Each three-dimensional connection element is of a protrusion type (122) (eg, “T” shaped). On another outer surface thereof, parallel to the outer surface bearing the three-dimensional protrusion-type connection element (122), the breadboard (120) includes one or more three-dimensional recess-type connection elements (124), each of which is shaped and dimensioned to allow insertion and locking of one of the three-dimensional protrusion-type connecting elements (122). The use of three-dimensional protrusion (122) and recess (124) type connectors allow two or more breadboards (120) to be locked together to create a larger panel with receptacles for electronic component terminals.

FIG. 1A also shows a third breadboard (130) which is rectangular (or square) in shape and includes one or more arrays (not shown) whose cells are receptacles for electronic component terminals. The third breadboard (130) includes on one of its external surfaces, substantially perpendicular to the surface carrying the one or more panels, one or more three-dimensional connection elements. Each three-dimensional connection element is a protrusion (132) type (eg, “Γ” or hook shaped). On another outer surface thereof, parallel to the outer surface bearing the three-dimensional projection-type connection element (132), the breadboard (130) includes one or more three-dimensional recess-type connection elements (134), each of which is shaped and dimensioned to allow insertion and locking of one of the three-dimensional protrusion-type connecting elements (132).

FIG. 1B shows a system consisting of a breadboard connected to an independent power supply according to the prior art. The system (100) includes a power supply (140) which is connected to an electrical outlet via a cable and plug (144) while alternatively or optionally includes a battery (142). The power supply (140) is also connected, via detachable cables (132), (134) to breadboard (110) for power supply. The power supply (140) has a large volume and weight compared to breadboard (110) and is therefore difficult to transport and use but also complicated and expensive to manufacture. At the same time as the power supply (140) and the breadboard (110) are independent devices and are loosely connected via detachable cables (132), (134) are difficult to handle in the field since the user has to handle two devices and are also prone to breakage of cables which can create additional problems.

The complete device (100) includes in its power supply (140) a variety of electronic circuits, including an AC transformer and rectifier so that it can be connected directly to a DC power outlet.

In an alternative embodiment the integrated device (100) includes a battery (142) for power supply. In another alternative embodiment, the integrated device (100) includes an AC transformer and rectifier, as well as, a battery for use both in areas with easy access to an electrical outlet, as well as in areas without an electrical outlet or during power outages (e.g. due to damage). The complete device (100) due to the transformer or the battery it includes has a large volume and weight compared to the breadboard (110), (410) and is therefore difficult to transport and use but also complicated and expensive to manufacture.

In other prior art breadboard examples, power supplies are used which include a USB port. In these breadboard examples the power supplies used are stand-alone devices which are connected via cables to the breadboard and are therefore difficult to use in the field.

### Innovative Problem Solution—Self-Locking Power Distributor for SPDIK

FIG. 2 shows a first example of a BBPPD implementation according to the present invention. The BBPPD (200) has a rectangular (or square) shape and includes on an outer surface (e.g. its upper surface) one or more arrays (not shown) whose cells are sockets for terminals of electronic components. BBPPD (200) includes on one of its outer surfaces, substantially perpendicular to the surface bearing the one or more arrays, one or more three-dimensional connection elements. Each three-dimensional connection element is of the square protrusion type (212). On another outer surface thereof, parallel to the outer surface bearing the three-dimensional protrusion-type connection element (212), the BBPPD (200) includes one or more three-dimensional recess-type connection elements (214), each of which is shaped and dimensioned to allow insertion and locking of one of the three-dimensional protrusion-type connecting elements (212). The use of three-dimensional protrusion (212) and recess (214) type connection elements allow the locking of two or more breadboards (e.g. BBPPD (200) with another breadboard) to create a larger array with sockets for electronic component terminals. The connectivity of BBPPD (200) with another breadboard is mainly used in a laboratory. In an alternative usage example, it can be used in the field.

The BBPPD (200) also has on its outer surface, substantially perpendicular to the surface bearing the one or more arrays and on the outer surface bearing the three-dimensional projection-type connection element (212), includes a USB-type connector (252) of any version (p. e.g. B, C, micro, etc.) for easy connection and power supply from any external Power Supply Device (PSD) (such as computer, smart phone, power bank, etc.), equipped with a USB connector of any version and type which can be connected to the USB socket of BBPPD (200). In one aspect the USB type connector (252) of BBPPD (200) is connected directly to the USB connector of the external PSD, while in another aspect it is connected via a USB cable. Two conductive lines or cables or wires are connected to the USB-type connector (252) of the UPS (200) to supply from the USB-type connector (252) voltage +5V (or any other voltage) and ground (GND), respectively, to a of Power Distribution Unit (PDU) and from it to the breadboard of BBPPD (200).

In alternative exemplary implementation, the socket can be of any type, such as e.g. barrel jack or other. Two conductive lines or cables or wires are connected to this socket for the supply from the socket of voltage (e.g. +5V or any other voltage) and ground (GND), respectively, to the PDU and from it to the breadboard of the BBPPD (200).

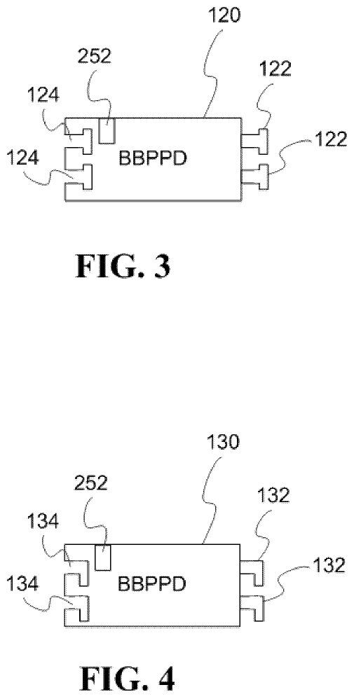

FIG. 3 shows a second example of a BBPPD implementation according to the present invention. BBPPD (300) is the same as BBPPD (200) with the only difference being the formatting of the three-dimensional connection elements which in BBPPD (300) are T-type protrusions (312). On another outer surface thereof, parallel to the outer surface bearing the three-dimensional projection-type connecting element (312), BBPPD (300) includes one or more three-dimensional recess-type connecting elements (314), each of which is shaped and dimensioned to allow insertion and locking of one of the three-dimensional protrusion-type connecting elements (312).

FIG. 4 shows a third example of a BBPPD implementation according to the present invention. BBPPD (400) is the same as the BBPPD (200), (300) with the only difference being the formatting of the three-dimensional connection elements which in the BBPPD (400) are of type “Γ” protrusion (412). On another outer surface thereof, parallel to the outer surface bearing the three-dimensional protrusion-type connection element (412), BBPPD (400) includes one or more three-dimensional recess-type connection elements (414), each of which is shaped and dimensioned to allow insertion and locking of one of the three-dimensional protrusion-type connecting elements (412).

In alternative exemplary implementations of the invention, the shaping of the three-dimensional connection elements of the BBPPD is a protrusion and recess of a parallelogram, triangular, prismatic, cylindrical, elliptical or other cross-section type.

The use of three-dimensional protrusion and recess type connection elements in the BBPPD allow the BBPPD to be secured with two or more breadboards to create a panel of larger dimensions with sockets for terminals of electronic components. Linking the BBPPD with two or more breadboards may be preferable for laboratory use, while using the BBPPD alone may be preferable for field use but can be used equally well in the laboratory. With its design, the BBPPD allows its use both in the laboratory and in the field, providing the same safety and ease of use in both cases. At the same time, it allows the use of existing external power sources which may be available both in the laboratory and in the field, thus achieving optimal use of the available devices as well as economy, while at the same time it allows the dimensioning of the breadboard which includes by connecting additional breadboards and securing them through the integrated three-dimensional locking elements, i.e. the three-dimensional protrusions and recesses.

In alternative embodiments of breadboard (200, 300, 400), the three-dimensional connection elements may have any other shape.

Exemplary of implementations of the UPS and breadboard arrangement within the BBPPD

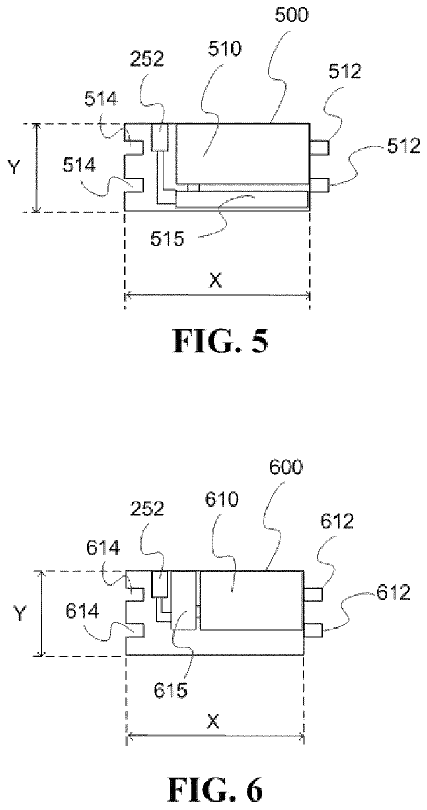

FIG. 5 shows a side view of a first example of arrangement and connection of PDU with the breadboard of the BBPPD. BBPPD (500) includes three-dimensional locking means with external breadboards consisting of recesses (512) and recesses (514), breadboard (510), PDU (515) and USB connector (252). The extension of the three-dimensional locking means and the relative position with respect to the breadoboard (510) is the same as exemplary systems (200), (300), (400). In order that the outer dimensions of BBPPD (500) are not significantly modified compared to standard external breadboards to which it is designed to be connected via the three-dimensional locking means, in the first example arrangement, the horizontal dimension X of BBPPD (500) is chosen to be the same as the corresponding standard dimension breadboard available on the market. Only the vertical dimension Z of the BBPPD (500) is increased to create enough space for the arrangement of the PDU (515) below breadboard (510) and the electrical connection of the two units (510), (515) to each other and the electrical connection of the PDU (515) with the USB connector (252). In this way it is still possible to connect BBPPD (500) with external breadboards. In addition, the specific implementation example allows the construction of BBPPD (500) using a breadboard of any dimensions and available on the market. Thus, BBPPD (500) will have the same X dimension as the breadboard (510) which will be used for its implementation but a larger Z dimension so that it is possible to include the arrangement of the PDU (515) below breadboard (510). This implies that BBPPD (500) will have a larger dimension Z than the corresponding dimension Z′ of the external breadboard to which it will be connected. The difference Z−Z′=Z″, where Z″ is the corresponding vertical dimension of the PDU (515) and which varies according to the size of the electronic components used in the implementation of the PDU (515). In any case, the combination of the profile and the configurations of the three-dimensional locking means of BBPPD (500) allows BBPPD (500) to be secured with external breadboards despite the difference between the corresponding dimensions Z and Z′.

In a modification of the first example of the implementation of BBPPD (500), a specially made breadboard (510) is used which has the same Z dimension as the Z′ dimension of an external breadboard. The dimensions of breadboard (510) are practically the dimensions of BBPPD (500), which includes PDU (515) made of low-profile electronics. Thus, the modified breadboard (510) (and therefore BBPPD (500)) can include the PDU (515) without increasing their vertical dimension Z.

FIG. 6 shows a side view of a second example of arrangement and connection of UPS with the breadboard of BBPPD. The BBPPD (600) includes three-dimensional locking means with external breadboards consisting of recesses (612) and recesses (614), breadboard (610), PDU (615) and USB connector (252). The extension of the three-dimensional locking means and the relative position with respect to breadboard (610) is the same as exemplary systems (200), (300), (400). In order that the outer dimensions of BBPPD (600) are not significantly modified compared to standard external breaadboards to which it is designed to be connected via the three-dimensional locking means, in the second arrangement example, the vertical arrangement Z of BBPPD (600) is chosen to be the same as the corresponding standard dimension breadboard available in the matter. Only the horizontal dimension X of BBPPD (600) is increased to create enough space for the PDU arrangement (615) next to breadboard (610) and the electrical connection of the two units (610), (615) to each other and the electrical connection of PDU (615) with the USB connector (252). In this way it is still possible to connect BBPPD (600) with external breadboards. In addition, the specific implementation example allows the construction of BBPPD (600) using breadboards of any dimensions and available on the market. Thus, BBPPD (600) will have the same Z dimension as breadboard (610) which will be used for its implementation but a larger X dimension so that it is possible to include the arrangement of the PDU (615) on the side of breadboard (610). This implies that BBPPD (600) will have a larger X dimension than the corresponding X′ dimension of the external breadboard to which it will be connected. The difference X−X′=X″, where X″ is the corresponding horizontal dimension of the PDU (615) and which varies according to the size of the electronic components used in the implementation of PDU (615). In any case, the combination of the profile and the dimensions of the three-dimensional locking means of BBPPD (600) allows the securing of BBPPD (600) with external breadboards as the difference between the corresponding dimensions X and X′ does not affect the connectivity of the two devices.

In a first modification of the second implementation example of BBPPD (600) a specially made breadboard (610) is used which has the same X dimension as the X′ dimension of an external SPDIK. The dimensions of breadboard (610) are practically the dimensions of BBPPD (600), which includes PDU (615) made of electronic components on a small board. Thus, the modified breadboard (610) (and therefore BBPPD (600)) can include the PDU (615) without increasing their horizontal dimension. The vertical dimension is not affected.

In a second modification of the second implementation example of BBPPD (600) a specially made breadboard (610) is used which has the same Y dimension as the Y′ dimension of the external breadboard.

In a third modification of the second implementation example of BBPPD (600) a specially made breadboard (610) is used which has the smallest dimension Y compared to the dimension Y′ of the external breadboard and/or smaller dimension X compared to the dimension X′ of the external breadboard. In this way, the dimensions of breadboard (610) are reduced, which implies fewer cells-sockets in breadboard (610). With this particular embodiment, BBPPD (600) also includes the PDU (615), without modifying the external dimensions of BBPPD (600).

### Example of Alternative MPI Implementation—With Voltage Selector

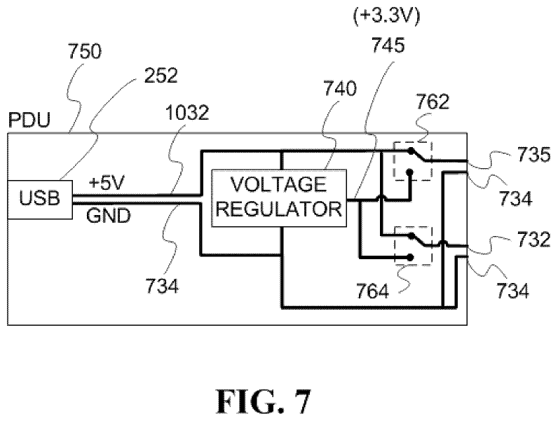

FIG. 7 shows an example of an alternative implementation of BBPPD (500), (600), which depicts only PDU (750) and which includes a voltage selector. Alternative BBPPD (700), includes a USB type connector (252) of any version (e.g. B, C, micro, etc.) for easy connection and power supply from any External PSD.

Two conductive lines (or cables or wires) (732), (734) are connected to the USB type connector (252) of BBPPD (700), for the supply of +5V voltage (or any other voltage) from the USB type connector (252) and ground (GND). Between the two conductive lines (732), (734) a voltage regulator (740) is connected which produces at its output a new voltage (e.g. +3.3V), different from the voltage of +5V (or any other voltage), and the new voltage is fed into a conductive line (745). Conductive lines (732), (734), (745) are then connected to first (762) and second (764) voltage selectors through which voltage selectors (762), (764) the user of BBPPD (700) can select the desired voltage and channel it to the output of BBPPD (700).

In modifications of the present example alternative embodiment, the two voltage selectors (762), (764) can be replaced by a multiple voltage selector, or more voltage regulators and/or voltage selectors can be added so that the user of the ASPDI can select more voltages, or the voltage selectors to be replaced by corresponding cable or wire receptacles to which the cables or wires (732), (734) and (735) connecting the PDU to breadboard (510), (610) or and with one or more external breadboard.

Alternative implementations of the present BBPPD include the use of a voltage regulator without the use of a voltage selector. In these alternative implementations, e.g. from the 5V provided by the USB socket, the voltage regulator produces e.g. 3.3 V and supplies the breadboard with 3.3 V. In another implementation example, the BBPPD supplies with 5V a first power line of the breadboard and with 3.3V a second power line of the same breadboard, without the use of a voltage selector.

In a modification of the present example of an alternative implementation of BBPPD, the PDU can receive from an external device, through the USB socket, 5V according to the USB standard. Alternatively, or additionally, the PDU can receive from an external device, through the USB socket (or another type of socket), any other voltage (e.g. 9V) using the protocol (and the corresponding subsystem in a compatible external device) USB Power Delivery (USB-PD).

In further modifications of the present example of an alternative implementation of the BBPPD, the BBPPD may include more voltage regulators, a dimmer, a voltmeter, an ammeter, for better regulation and monitoring of the operating parameters of the BBPPD, and/or a battery to enable the use of the BBPPD in the field without the need to provide USB power from an external PSD.

In example embodiments where the BBPPD includes a battery, the BBPPD may also include one or more USB outputs (of the same or different types), combined with suitable circuitry, thus allowing the device to also function as a powerbank.

In all the implementation examples presented above, the BBPPD can carry one or more USB sockets of a different type each. It can also carry, in addition to or as an alternative to one or more USB sockets, sockets for plugs or plugs suitable for supplying power from power sources alternative to the sources that provide a USB connection. In this case, it is up to the user of the BBPPD to ensure that the alternative power source provides protection against overvoltage, etc.

All voltages (i.e. potential differences) mentioned in this description are for direct current (DC). Mechanical stresses are not about potential difference.

In all the examples of implementation presented above, the BBPPD has one or more protrusions and/or recesses. However, these implementation examples can be modified so that the BBPPD does not have any protrusion and/or recess. In these modified implementation examples the BBPPD can be connected to one or more breadboards through other securing means known from the literature, e.g. wires, cables, clips, Velcro, etc.

The examples used above to describe the present innovative solution should not be considered as limiting the scope of the present innovative solution. The present innovative solution can be applied in other scenarios and settings than those described in the examples presented above.

The average person skilled in the art will understand that the shape, proportions and dimensions of the parts of the present invention, as shown in the exemplary embodiments, may be modified without departing from the scope and intended protection of the present invention.

The above descriptions of exemplary embodiments are simplified and do not include parts that are used in the embodiment but are not part of the present invention, are not necessary to the understanding of the invention and are obvious to an average person with relevant knowledge of the art related to the invention. In addition, variations of the exemplary embodiments are possible where, for example, certain elements of the exemplary embodiments may be rearranged, omitted and replaced with equivalents or new ones may be added, and existing elements may be interconnected in a manner different from that described, with the condition that the different wiring is compatible with the technical effect that the elements of the invention have, being technical characteristics of the invention. Similarly, modification of the shape and dimensions of the illustrated parts is considered to be within the scope of protection of the present invention to the extent that such modifications are obvious to persons skilled in the relevant art and to the extent that such modifications are equivalent to the exemplary embodiments presented or do not add tangible and unexpected or non-obvious improvements to the technical result they offer.

Thus, the present text is not intended to be limited only to the exemplary embodiments of the invention presented but is to be given the widest possible scope in accordance with the principles and novel features it discloses.

Unless otherwise specifically stated, it is the intention of the inventor to give to the words and phrases mentioned in the description of the invention and the claims the ordinary and generally accepted meanings attributed to the average person with relevant knowledge of the related art with the present invention.

The foregoing description of a preferred embodiment and best mode of carrying out the invention known to the applicant at the time of filing has been presented and is intended for the purposes of illustration and description. It is not intended to be exhaustive or to limit the invention to the precise form disclosed and many modifications and variations are possible in light of the above teachings. The embodiment has been selected and described to better explain the principles of the invention and its practical application and to enable others skilled in the art to better utilize the invention in various application scenarios and modes of use and with various modifications as are appropriate to the specific use under consideration. Therefore, it is intended that the invention is not limited only to the specific details disclosed for carrying out the invention, but that the invention includes everything that falls within the scope of the appended claims.

1. Self-locking Breadboard with Built-in Portable Power Distributor (BBPPD) (200), (300), (400), (500), (600) comprising a breadboard (510), (610) electrically connected to a Power Distribution Unit (PDU) (515), (615) wherein the PDU (515), (615) comprises a power input and output with two conductive lines configured for supplying voltage and ground at least to the breadboard (510), (610), the breadboard (510), (610) comprises at least one array (260) placed on an external surface of the BBPPD (200), (300), (400), (500), (600), wherein the at least one array (260) comprises cells, wherein the cells are sockets for terminals of electronic components, and wherein BBPPD (200), (300), (400), (500), (600) is characterized in that:
the BBPPD (200), (300), (400), (500), (600) is configured for connecting to an external breadboard (580) using integrated locking means;
the PDU (515), (615) is part of the breadboard (510), (610);
the power input includes a socket (252) electrically connected to the PDU (515), (615) and configured for receiving a first voltage and a ground from an external power supply device and for providing the first voltage and the ground to the PDU (515), (615);
the locking means are non-electrically connected to the breadboard (510), (610), the PDU (515), (615) and the socket (252); and
PDU (515), (615) is configured for optionally generating a second voltage from the first voltage and for providing the first voltage or the second voltage and the ground to the breadboard (510), (610).

2. BBPPD (200), (300), (400), (500), (600) according to claim 1, wherein the locking means are (a) at least one three-dimensional protrusion-type connection element (112), (122), (132), (512), (612) formed on a first outer surface of the BBPPD (200), (300), (400), (500), (600) substantially perpendicular to the external surface bearing the at least one array (260), and (b) at least one three-dimensional recess-type connection element (114), (124), (134), (514), (614) formed on a second outer surface of the BBPPD (200), (300), (400), (500), (600) substantially perpendicular to the external surface bearing the at least one array (260) and parallel to the first outer surface.

3. BBPPD (200), (300), (400), (500), (600) according to claim 1, wherein the locking means are selected from wires, cables, clips, and a pair of tapes, wherein one tape comprises tiny loops and another tape comprises tiny hooks configured for locking to each other when touched to each other, and for unlocking by detaching the one tape from the another tape.

4. BBPPD (200), (300), (400), (500), (600) according to claim 1, wherein the socket (252) is a Universal Serial Bus (USB) connector (252).

5. BBPPD (200), (300), (400), (500), (600) according to claim 1, wherein the socket is of a barrel jack or a molex type.

6. BBPPD (200), (300), (400), (500), (600) according to claim 2, wherein the at least one three-dimensional protrusion-type connecting element (112), (122), (132), (512), (612) and the at least one three-dimensional recess-type connection element (114), (124), (134), (514), (614) are shaped for having a cross-section selected among a square, a rectangular, a triangular, a cylindrical and a prismatic cross-section.

7. BBPPD (200), (300), (400), (500), (600) according to claim 1, which additionally comprises at least one of:
at least one voltage regulator (740), each configured for generating one of at least a second voltage;
at least one voltage selector (762, 764), each configured for selecting the one of the at least second voltage;
a dimmer switch;
a voltmeter;
an ammeter; and
a battery.

8. BBPPD (200), (300), (400), (500), (600) according to claim 1, wherein the PDU (515), (615) comprises at least one USB output.

9. Power supply system, comprising:
at least two BBPPD (200), (300), (400), (500), (600) according to claim 1; and
an external power supply device, electrically connected to a socket (252) of one of the at least two BBPPD (200), (300), (400), (500), (600);
wherein the at least two BBPPD (200), (300), (400), (500), (600), are electrically connected to each other and to the PDU (515), (615).

10. A method for providing power to a system according to claim 9, wherein the method comprises:
mechanically connecting a BBPPD to another BBPPD by securing at least one three-dimensional connection element of protrusion (112), (122), (132), (512), (612) or recess type (114), (124), (134), (514), (614) of the BBPPD (200), (300 ), (400), (500), (600) with at least one compatible three-dimensional connection element of the another BBPPD;
electrically connecting a PDU (515), (615) of the BBPPD (200), (300), (400), (500), (600) with a PDU of the another BBPPD through a first cable for voltage supply and a second cable for ground supply; and
electrically connecting the BBPPD (200), (300), (400), (500), (600), through a socket (252) with a socket of an external power supply device for providing a first voltage and ground from the external power supply device to the BBPPD (200), (300), (400), (500), (600).

11. A method according to claim 10, the method further comprising selecting a second voltage for suppling to the breadboard (510), (610) by using one of:
one of at least one voltage selector (762, 764) of the PDU (515), (615), wherein the one of the at least one voltage selector (762, 764) selects the second voltage and routes it to an output of the PDU (515), (615), and wherein the second voltage is generated by one of at least one voltage regulator (740) of the PDU (515), (615);
one of at least one voltage regulator (740) whose output is directly connected to the output of the PDU (515), (615);
a USB Power Delivery protocol, which protocol allows the PDU (515), (615) to receive the second voltage from the external power supply device and distribute the second voltage to the output of the PDU (515), (615); and
a USB Power Delivery protocol, which protocol allows the PDU (515), (615) to receive the second voltage from the external power supply device and to generate at least one third voltage and to distribute the at least one third voltage to at least another output of the PDU (515), (615).

12. (canceled)
